(19) United States
(12) Patent Application Publication
(10) Pub. No.: US 2010/0102834 A1
(43) Pub. Date: Apr. 29, 2010

(54) Sensor switch for sensing human body contact

(75) Inventor: Irn Shyu, Tainan Hsien (TW)

Correspondence Address: BACON & THOMAS, PLLC, 625 SLATERS LANE, FOURTH FLOOR, ALEXANDRIA, VA, 22314-1176, US

(73) Assignee: Ya Horng Electronic Co., Ltd., Tainan Hsien (TW)

(21) Appl. No.: 12/585,257

(22) Filed: Sep. 10, 2009

(30) Foreign Application Priority Data
Oct. 23, 2008 (TW) 097218965

(51) Int. Cl. G01R 27/08

(52) U.S. Cl. 324/692

(57) ABSTRACT

This invention is a sensor switch capable of sensing the contact by human body, comprising a contact conductor, issuing a signal once a human body touches it; a frequency generator, for the receiving of the signal issued by the contact conductor, converting the signal into a preset frequency to output; and a detecting circuit, for the receiving of the signal issued by the frequency generator, determining if the output frequency of the frequency generator is changed and issuing an electric signal subject to the frequency that is detected. Accordingly, once a human body gets in contact with the contact conductor, the detecting circuit will issue an electric signal to form a sensor switch.

### BACKGROUND OF THE INVENTION

1. Field of the Invention

This invention relates generally to a sensor switch and more specifically to one capable of sensing the contact by human body as the input signal, followed by the conversion of that signal to an electric signal for the next stage.

2. Description of the Prior Art

Prior art CD/MP3 players, DJ laser turntables, food stirrers and juicers all have mechanical buttons as the control switch, where the mechanical button has not only mechanical wastage but a built-in retard for its manipulation process. Besides, a mechanical switch is bulky, which deteriorates substantially the outlooks; hence, switches that sense the contact by human body were gradually under research to improve those drawbacks of the prior art. The inventor has made substantial improvement on the sensor switch that is capable of sensing the contact by human body, and that efforts gave birth to this invention.

### SUMMARY OF THE INVENTION

The objective of this invention is to provide a sensor switch which is capable of sensing the contact by human body as the input signal, followed by the conversion of that signal into an electric signal for an output.

The invention is characterized primarily by having: a contact conductor, issuing a signal as a human body touches it; a frequency generator, for the receiving of the signal issued by the contact conductor, converting the signal into a preset frequency to output; and a detecting circuit, for the receiving of the signal issued by the frequency generator, determining if the output frequency of the frequency generator is changed and issuing an electric signal subject to the frequency that is detected; therefore, once a human body gets in contact with the contact conductor, the detecting circuit will issue an electric signal to form a sensor switch.

### BRIEF DESCRIPTION OF THE DRAWINGS

FIG. 1 is a block flow chart of the first embodiment of this invention;

FIG. 2 is a circuit diagram of the first embodiment of this invention;

FIG. 3 is a block flow chart of the second embodiment of this invention; and

FIG. 4 is a circuit diagram of the second embodiment of this invention.

### DETAILED DESCRIPTION OF THE INVENTION

To achieve the aforesaid objects and function of the present invention, the technique and structure adopted are detailed described with reference to the following preferred embodiments and the accompanying drawings, which would give a thorough comprehension on the present invention.

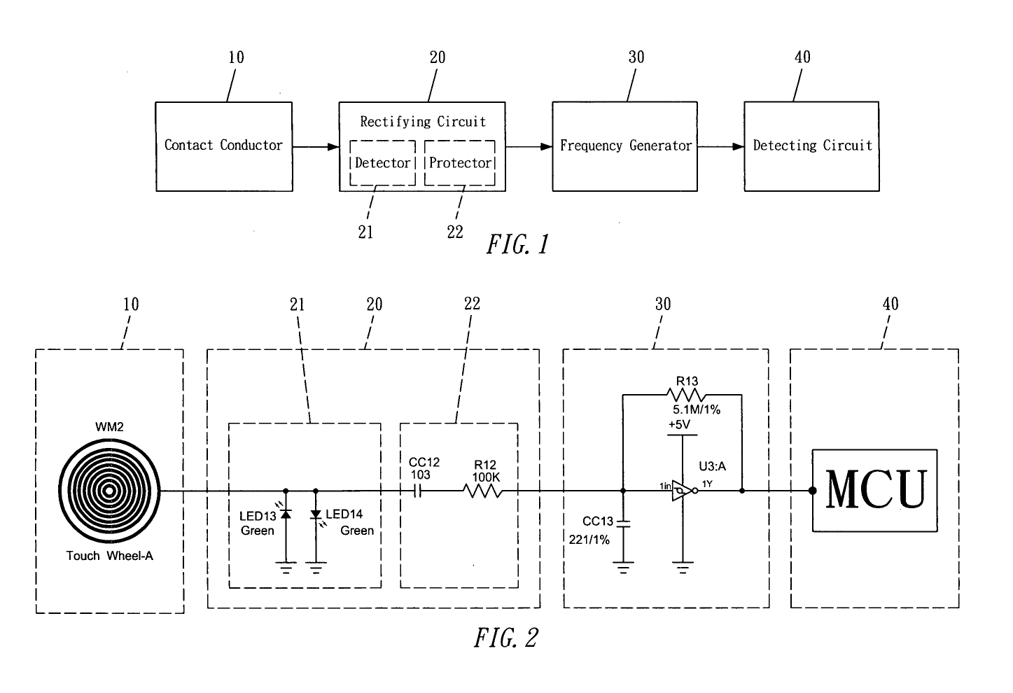

Referring to the block flow chart and the circuit diagram of the first embodiment of this invention shown in FIGS. 1 & 2, the sensor switch of this invention comprises:
a.) a contact conductor 10, issuing a signal as a human body touches the contact conductor 10. Before the touch of the contact conductor 10 by the human body, the frequency is set low in the contact conductor 10. Once the human body touches the contact conductor 10, the contact conductor 10 senses the frequency of the human body (the frequency of the human body from the power source 60/50 Hz) and outputs it.
b.) a rectifying circuit 20, not an essential element, connected to the output end of the contact conductor 10, responsible for smoothly shaping the signals and avoiding a sudden surge, for the protection of the circuitry. The rectifying circuit 20 is made up of a detector 21 and a protector 22, where the input signal with excessive amplitude from the contact conductor 10 is truncated by the detector 21 into a safety value for the use by the next stage to avoid excessive voltage. The protector 22 is responsible for blocking direct current and allowing the alternate current of human body to pass, and for making use of current limiting for the current protection when the detector 21 at the previous stage ceases to be effective.
c.) a frequency generator 30, connected to the output end of the rectifying circuit 20, generating a square waveform in the frequency range: 1.2 KHz˜2.3 KHz during no human body getting in contact with the contact conductor 10. Once a human body touches the contact conductor 10, the frequency generator 30 makes a change to issuing a 50/60 Hz frequency signal;
d.) a detecting circuit 40, connected to the output end of the frequency generator 30, capable of detecting the output frequency of the frequency generator 30 and reacting subject to the detected frequency. For instance, a signal of frequency 1.2 KHz˜2.3 KHz is detected, it means there is no human body to get in touch with the contact conductor 10. On the other hand, if a 50/60 Hz frequency is detected, it surely means that a human body touches the contact conductor 10, and the detecting circuit 40 will issue an electric signal to form a switch. The detecting circuit 40 may be a MCU (that is, a microcontroller or a microprocessor) shown in FIG. 2.

During operating phase:
1. As a human body doesn't touch the contact conductor 10, the contact conductor 10 has a setting of low frequency, and the frequency generator 30 will generate a high frequency 1.2 KHz˜2.3 KHz square waveform automatically. As the detecting circuit 40 detects the high frequency waveform from the frequency generator 30, it recognizes that there is no human body to touch the contact conductor 10 and without issuing an electric signal.
2. Once a human body touches the contact conductor 10, the contact conductor 10 detects the frequency of the human body from the power source 50/60 Hz. And a signal corresponding to the human body frequency is outputted from the rectifying circuit 20 to the frequency generator 30 at the next stage; the frequency generator 30 replaces its original high frequency (1.2 KHz˜2.3 KHz) with the 50/60 Hz frequency and outputs it to the detecting circuit 40 at the next stage. As the detecting circuit 40 detects the output frequency of the previous stage, it issues an electric signal, and the switch forms a connecting state.

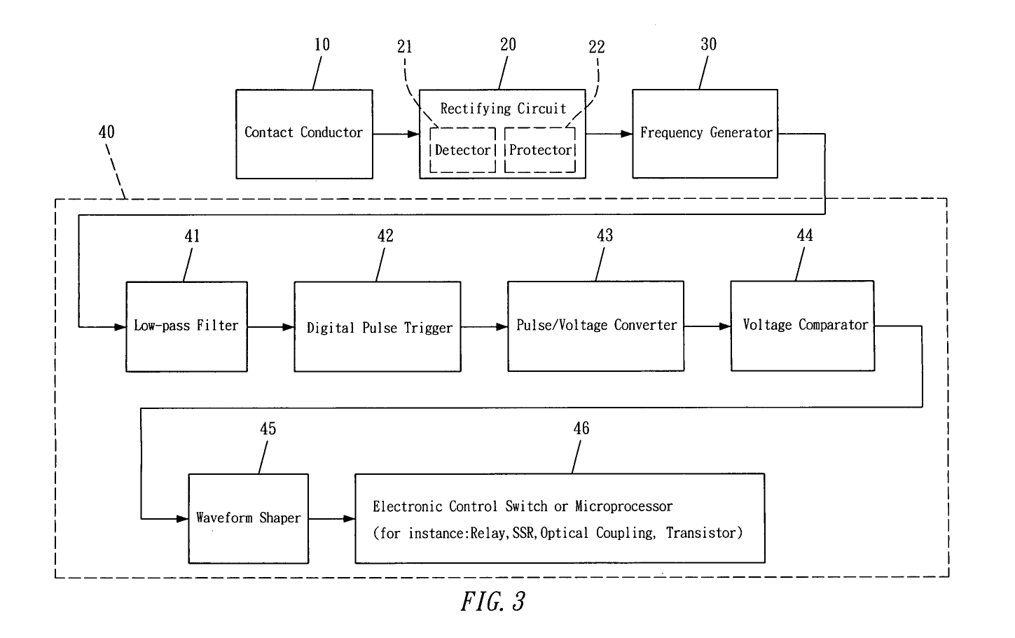

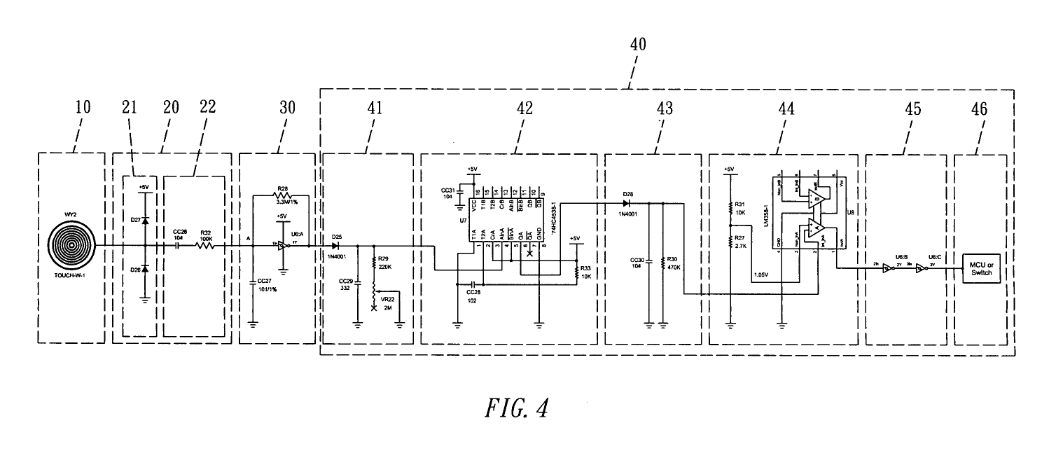

Referring to the block flow chart and the circuit diagram of the second embodiment of this invention shown in FIGS. 3 & 4, and like the first embodiment of this invention, this embodiment comprises a contact conductor 10, a rectifying circuit 20, a frequency generator 30 and a detecting circuit 40. The major difference between the two embodiments lies in that the detecting circuit 40 of the second embodiment is made of a plurality of circuits. This detecting circuit 40 comprises:
1.) a low-pass filter 41, featuring blocking high frequencies and allowing low frequencies to pass, which is to filter out the high frequency waveforms generated by the frequency generator 30 due to no human body getting in touch with the contact conductor 10. Once the contact conductor 10 is touched by a human body, a low-frequency signal generated by the frequency generator 30 is allowed to pass by the low-pass filter.
2.) a digital pulse trigger 42, categorized as a monostable multivibrator, converting a low frequency pulse signal (a symmetry signal) coming from the low-pass filter 41 into a high frequency asymmetric pulse signal;
3.) a pulse/voltage converter 43, a charge/discharge loop, as a human body touches the contact conductor 10, the pulse signal from the digital pulse trigger 42 at the previous stage charges a plurality of times successively, and a capacitor C will be charged to a high (Hi) level. As the human body is separated from the contact conductor 10, the capacitor is not being charged anymore. Actually, it is slowly discharged through a resistor R, until the discharge is accomplished.
4.) a voltage comparator 44, used for the comparison with the charge/discharge loop voltage of the pulse/voltage converter 43 at the previous stage. As the charge/discharge loop voltage is in a Hi level, the voltage comparator 44 issues a low (Low) signal, while the charge/discharge loop voltage is in a Low level, the voltage comparator 44 issues a Hi signal.
5.) a waveform shaper 45, not an essential element, for shaping the output signal of the voltage comparator 44 into complying digitized voltage levels, for instance, logic 0 (0V), logic 1 (5V).
6.) an electronic control switch or a microprocessor 46, for the receiving of the output digital signals (logic 0/1) of the waveform shaper 45 at the previous stage, to drive easily the active components to achieve the control of ON/OFF of the switch.

It is apparent from the aforesaid two embodiments that this invention is made up of a contact conductor 10, a frequency generator 30 and a detecting circuit 40, which together to accomplish the purpose—sensing human body contact as the signal to input, by converting into an electric signal for an output, to achieve the control ON/OFF of the switch. The constitution and function is construed to be creative and useful, which is compliant to the utility patent requirements. An application is now for filing utility patent according to the law, which deserves your favorable examination and approval.

What is claimed is:

1. A sensor switch capable of sensing the contact by human body, comprising:
1.) a contact conductor, issuing a signal of human body frequency once a human body touching said contact conductor;
2.) a frequency generator, for the receiving of the signal issued by said contact conductor at the previous stage, generating a high frequency square waveform during no human body getting in contact with said contact conductor; once a human body touching said contact conductor, said frequency generator making a change into issuing the signal of human body frequency; and
3.) a detecting circuit, connected to the output end of said frequency generator, capable of detecting the output frequency of said frequency generator and reacting subject to the detected frequency; once a high frequency being detected, it meaning no human body being touched; on the other hand, once a human body frequency being detected, it surely meaning that a human body gets in contact with said contact conductor, and said detecting circuit issuing an electric signal to form a switch.

2. A sensor switch capable of sensing the contact by human body as in claim 1 wherein a rectifying circuit may be placed between said contact conductor and said frequency generator, and the rectifying circuit being connected to the output end of said contact conductor; the rectifying circuit being made up of a detector and a protector, where the input signal with excessive amplitude from said contact conductor is truncated by the detector into a safety value for using by the next stage to avoid excessive voltage; the protector, responsible for blocking direct current and allowing the alternate current of human body to pass, and for making use of current limiting for the current protection when the detector ceases to be effective.

3. A sensor switch capable of sensing the contact by human body as in claim 1 wherein the detector is a micro-controller.

4. A sensor switch capable of sensing the contact by human body as in claim 1 wherein the detector is a microprocessor.

5. A sensor switch capable of sensing the contact by human body as in claim 1 wherein the detector comprises:
1.) a low-pass filter, featuring blocking high frequencies and allowing low frequencies to pass, which is to filter out the high frequency waveforms generated by said frequency generator due to no human body in touch with said contact conductor; once said contact conductor being touched by human body, a low-frequency signal generated by said frequency generator being allowed to pass the low-pass filter;
2.) a digital pulse trigger, categorized as a monostable multivibrator, converting the low frequency pulse signals from the low-pass filter into high frequency asymmetric pulse signals;
3.) a pulse/voltage converter, a charge/discharge loop, as a human body touching said contact conductor, a pulse signal from the digital pulse trigger at the previous stage charging a plurality of times successively, and a capacitor being charged to a high (Hi) level; as the human body being separated from said contact conductor, the capacitor being not charged anymore, it actually slowly discharging through a resistor, until the discharge being accomplished;
4.) a voltage comparator, used for the comparison with the charge/discharge loop voltage of the pulse/voltage converter at the previous stage; once the charge/discharge loop voltage is a Hi level, the voltage comparator issuing a low (Low) signal; while the charge/discharge loop voltage is a Low level, the voltage comparator issuing a Hi signal; and
5.) an electronic control switch or a microprocessor, for the receiving of the output signals of the voltage comparator to drive the active components to achieve the control of ON/OFF of the switch.

6. A sensor switch capable of sensing the contact by human body as in claim 5 wherein a waveform shaper may be placed in between the voltage comparator and the electronic control switch or a microprocessor of the detector, for shaping the output signal of the voltage comparator into complying digitized voltage levels.
